(19) United States
(12) Patent Application Publication
(10) Pub. No.: US 2025/0311234 A1
(43) Pub. Date: Oct. 2, 2025

(54) FERROELECTRIC MEMORY STRUCTURE

(71) Applicants: Materials Analysis Technology Inc., Hsinchu County (TW); National Tsing Hua University, Hsinchu City (TW)

(72) Inventors: Yung-Hsien Wu, Hsinchu City (TW); Yi-Fan Chen, New Taipei City (TW); Hung-Yuan Shih, New Taipei City (TW); Chen-Hsin Wang, Taoyuan City (TW); Chun-Yi Kuo, Taipei City (TW); HUNG-JEN CHEN, Hsinchu City (TW)

(21) Appl. No.: 19/088,304

(22) Filed: Mar. 24, 2025

Related U.S. Application Data
(60) Provisional application No. 63/572,397, filed on Apr. 1, 2024.

(51) Int. Cl. H10B 53/30

(52) U.S. Cl. CPC H10B 53/30

(57) ABSTRACT

A ferroelectric memory structure includes a first ferroelectric material layer and a first metal compound layer. The first metal compound layer is adjacently attached to a surface of the first ferroelectric material layer. The first ferroelectric material layer and the first metal compound layer are successively formed by an atomic layer deposition process.

### CROSS-REFERENCE TO RELATED PATENT APPLICATION

This application claims the benefit of priority to the U.S. Provisional Patent Application Ser. No. 63/572,397, filed on Apr. 1, 2024, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a ferroelectric memory structure, and more particularly to a ferroelectric memory structure manufactured by using an atomic layer deposition process.

### BACKGROUND OF THE DISCLOSURE

Ferroelectric materials are materials having spontaneous polarization. That is, in the absence of an electric field, the positive/negative charge centers in a unit cell structure of the ferroelectric materials are separated to form an electric dipole.

In the field of memory technology, a “ferroelectric memory” is attracting much attention from the relevant industry, and may become the foundation for the next stage of in-memory computing. In the existing technology, hafnium dioxide (HfO₂) is used as the material of ferroelectric memory. Hafnium dioxide not only has high polarization density to greatly reduce an area of a memory cell, but also possesses good coating conformal properties that are conducive to constructing highly integrated 3D structures by using the semiconductor manufacturing process.

However, in the existing technology, contaminants or oxides may be introduced during the production process of ferroelectric memory materials. The contaminants or oxides will affect the binding ability of ferroelectric memory materials and electrode layers, thereby affecting the performance of ferroelectric memory elements, and reducing the durability and polarization capabilities thereof.

Therefore, how to enhance the performance of the ferroelectric memory elements through improvements in structural design so as to overcome the above-mentioned problems, has become one of the important issues to be addressed in the relevant industry.

### SUMMARY OF THE DISCLOSURE

In order to solve the above-mentioned problems, one of the technical aspects adopted by the present disclosure is to provide a ferroelectric memory structure. The ferroelectric memory structure includes a first ferroelectric material layer and a first metal compound layer. The first metal compound layer is adjacently attached to one surface of the first ferroelectric material layer. The first ferroelectric material layer and the first metal compound layer are successively formed by an atomic layer deposition process.

In one of the possible or preferred embodiments, the ferroelectric memory structure further includes a second metal compound layer adjacently attached to another surface of the first ferroelectric material layer. The first metal compound layer, the first ferroelectric material layer, and the second metal compound layer are sequentially and successively formed by the atomic layer deposition process.

In one of the possible or preferred embodiments, the ferroelectric memory structure further includes an electrode layer connected to the first metal compound layer or the second metal compound layer.

In one of the possible or preferred embodiments, the ferroelectric memory structure further includes a second ferroelectric material layer. The first ferroelectric material layer, the first metal compound layer, and the second ferroelectric material layer are sequentially and successively formed by the atomic layer deposition process.

In one of the possible or preferred embodiments, the ferroelectric memory structure further includes an electrode layer connected to the first ferroelectric material layer or the second ferroelectric material layer.

In one of the possible or preferred embodiments, the ferroelectric memory structure further includes a second metal compound layer, a second ferroelectric material layer, and a third metal compound layer. The first metal compound layer, the first ferroelectric material layer, the second metal compound layer, the second ferroelectric material layer, and the third metal compound layer are sequentially and successively formed by the atomic layer deposition process.

In one of the possible or preferred embodiments, the ferroelectric memory structure further includes an electrode layer connected to the first metal compound layer or the third metal compound layer.

In one of the possible or preferred embodiments, the first metal compound layer includes a first deposition layer and a second deposition layer, and compositions of the first deposition layer and the second deposition layer are different from each other.

In one of the possible or preferred embodiments, the material of the first metal compound layer includes at least an oxygen-containing compound or a nitrogen-containing compound formed of any one of tantalum, titanium, and aluminum.

In one of the possible or preferred embodiments, a thickness of the first metal compound layer is less than or equal to 20 nm.

The ferroelectric memory structure of the present disclosure can be used in memory elements having different structures such as FeRAM, FeFET, and FTJ memories.

Therefore, in the ferroelectric memory structure provided by the present disclosure, by virtue of “the first ferroelectric material layer and the first metal compound layer being successively formed by an atomic layer deposition,” the first metal compound layer can be a blocking layer to block atomic diffusion and reduce interface defect density between ferroelectric material layers and electrode layers, thereby reducing an interface resistance value and adjusting a stress of the ferroelectric material layer. The ferroelectric memory structure can be applied to ferroelectric memory elements to achieve characteristics of low voltage, high-speed operation, and high reliability.

Furthermore, according to certain embodiments, the ferroelectric memory structure includes two ferroelectric material layers and one metal compound layer. The one metal compound layer serves as a division layer, such that crystallographic orientations of the two ferroelectric material layers are consistent, thereby improving ferroelectric characteristics of the ferroelectric memory element. Therefore, when the ferroelectric memory structure is used in the ferroelectric memory element, characteristics of low voltage, high-speed operation and high reliability can also be realized.

Moreover, according to certain embodiments, a material of the metal compound layer is TaN. The metal compound layer formed by an atomic layer deposition is used as an intermediate layer for effectively improving durability and a crash time of the ferroelectric memory element that uses the metal compound layer, such that the ferroelectric memory element can sustain a continuous operation under a high electric field for a long period of time.

In addition, according to certain embodiments, the ferroelectric memory structure includes two ferroelectric material layers and one metal compound layer. Since the one metal compound layer divides the two ferroelectric material layers, after an annealing process, a crystal size of the ferroelectric material can be effectively reduced, an operation speed can be improved, and an operation voltage lowered.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic structural diagram of a ferroelectric memory structure according to a first embodiment of the present disclosure;

FIG. 2 is a schematic structural diagram of the ferroelectric memory structure according to a second embodiment of the present disclosure;

FIG. 3 is a schematic structural diagram of the ferroelectric memory structure according to a third embodiment of the present disclosure;

FIG. 4 is a schematic diagram comparing the structure of the ferroelectric memory according to one embodiment of the present disclosure and the structure of a ferroelectric memory in the related art; and

FIG. 5 is another schematic diagram comparing the structure of the ferroelectric memory according to one embodiment of the present disclosure and the structure of the ferroelectric memory in the related art.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

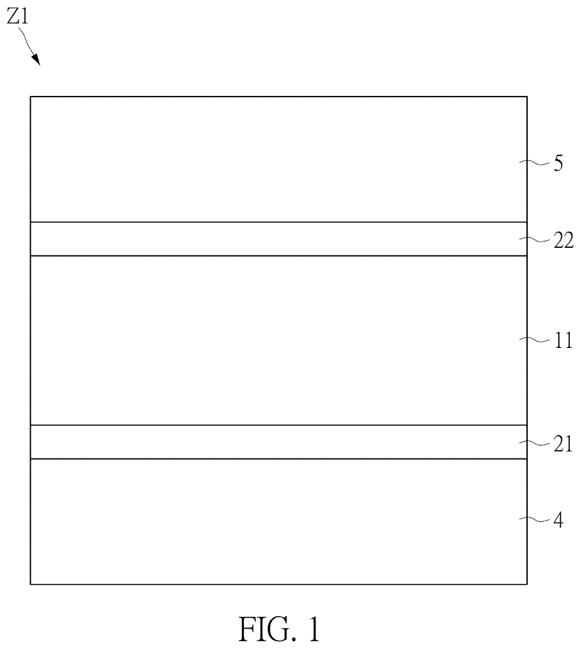

Reference is made to FIG. 1, which is a schematic structural diagram of a ferroelectric memory structure Z1 according to a first embodiment of the present disclosure. The ferroelectric memory structure Z1 includes a first ferroelectric material layer 11 and a first metal compound layer 21. The first metal compound layer 21 is adjacently attached to a surface of the first ferroelectric material layer 11, and the first ferroelectric material layer 11 and the first metal compound layer 21 are formed successively by way of atomic layer deposition (ALD). Since the first ferroelectric material layer 11 and the first metal compound layer 21 are produced in a same chamber and in a vacuum environment, the interface quality between the first metal compound layer 21 and the first ferroelectric material layer 11 has low defect density, thus indicating that no other oxide layer or oxide is generated between the first ferroelectric material layer 11 and the first metal compound layer 21.

The aforementioned ferroelectric material layer is such as HfO₂ or HfZrOx. In certain embodiments, the ferroelectric material layer may also be BaTiO₃ (BTO) or zirconate titanate (PbZrTiO₃, PZT), and the present disclosure is not limited thereto.

According to the embodiment shown in FIG. 1, the ferroelectric memory structure Z1 further includes a second metal compound layer 22, and the second metal compound layer 22 is adjacently attached to another surface of the first ferroelectric material layer 11. The first metal compound layer 21, the first ferroelectric material layer 11, and the second metal compound layer 22 are sequentially and successively formed by atomic layer deposition. That is to say, the first metal compound layer 21, the first ferroelectric material layer 11, and the second metal compound layer 22 are produced in the same chamber and in a vacuum environment. Accordingly, no oxide layer or oxide is formed between the first metal compound layer 21 and the first ferroelectric material layer 11, and between the first ferroelectric material layer 11 and the second metal compound layer 22.

Furthermore, according to the embodiment as shown in FIG. 1, the ferroelectric memory structure Z1 further includes two electrode layers 4 and 5 that are electrically connected to the first metal compound layer 21 and the second metal compound layer 22, respectively. However, the present disclosure is not limited thereto. A user can proceed to provide other film layers on the two electrode layers 4 and 5 according to practical requirements. For example, the electrode layer 4 is connected to the first metal compound layer 21, and after other functional film layers are deposited or disposed on the second metal compound layer 22, the electrode layer 5 is then disposed on the second metal compound layer 22 to complete the ferroelectric memory element according to requirements.

According to certain embodiments, after the second metal compound layer 22 is deposited, plasma can be used to modify a surface of the second metal compound layer 22 for repairing defects on the surface of the second metal compound layer 22.

### Second Embodiment

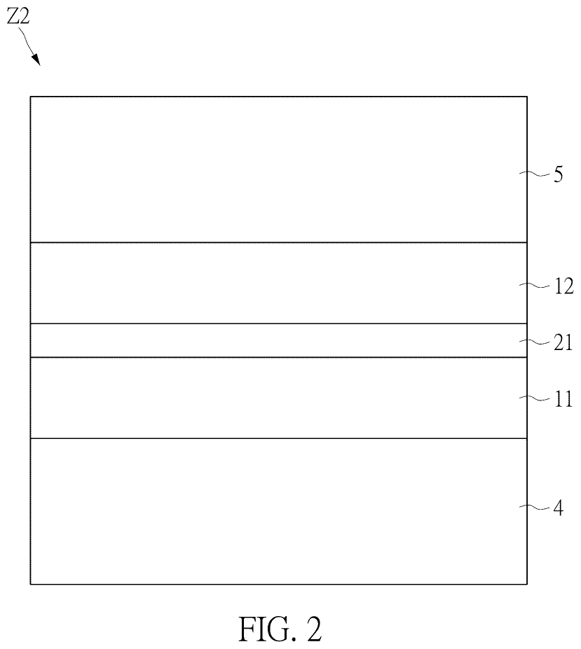

Reference is made to FIG. 2, and FIG. 2 is a schematic structural diagram of a ferroelectric memory structure Z2 according to a second embodiment of the present disclosure. The ferroelectric memory structure Z2 further includes a second ferroelectric material layer 12. According to the embodiment shown in FIG. 2, the first ferroelectric material layer 11, the first metal compound layer 21, and the second ferroelectric material layer 12 are sequentially and successively formed by atomic layer deposition. As mentioned above, since the first ferroelectric material layer 11, the first metal compound layer 21, and the second ferroelectric material layer 12 are produced in the same chamber and in a vacuum environment, the interface quality between the first ferroelectric material layer 11 and the first metal compound layer 21, and between the first metal compound layer 21 and the second ferroelectric material layer 12 has low defect density, thus indicating that no other oxide layer or oxide is generated in the two interfaces.

Furthermore, according to the embodiment shown in FIG. 2, the ferroelectric memory structure Z2 further includes two electrode layers 4 and 5 electrically connected to the first ferroelectric material layer 11 and the second ferroelectric material layer 12, respectively. However, the present disclosure is not limited thereto. The user can proceed to provide other film layers on the two electrode layers 4 and 5 according to requirements. For example, the electrode layer 4 is connected to the first ferroelectric material layer 11, and after other functional film layers are deposited or disposed on the second ferroelectric material layer 12, the electrode layer 5 is then disposed on the second ferroelectric material layer 12 to complete the ferroelectric memory element according to requirements.

The following is a manufacturing process to illustrate steps for manufacturing the ferroelectric memory structure Z2 of the embodiment shown in FIG. 2. First, an electrode layer 4 (having a thickness of such as 100 nm) is provided. The first ferroelectric material layer 11 (having a thickness of such as 5 nm), the first metal compound layer 21 (having a thickness of such as 2 nm), and the second ferroelectric material layer 12 (having a thickness of such as 5 nm) are successively deposited on the electrode layer 4. Afterwards, another electrode layer 4 (having a thickness of such as 100 nm) is disposed on the second ferroelectric material layer 12. Then, an annealing process is performed, for example, a temperature of the ferroelectric memory structure Z2 is increased to 400° C. and maintained for 30 seconds. The annealing process can reduce a grain size of a ferroelectric material layer, so as to repair defects in the interface between a metal compound layer and the ferroelectric material layer. In certain embodiments, the electrode layer 4 is formed by physical vapor deposition.

### Third Embodiment

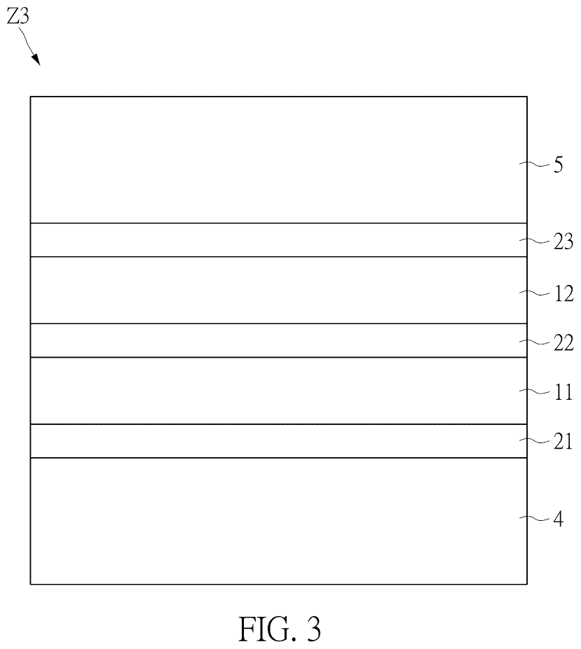

Reference is made to FIG. 3, in which FIG. 3 is a schematic structural diagram of a ferroelectric memory structure Z3 according to a third embodiment of the present disclosure. The ferroelectric memory structure Z3 further includes a second metal compound layer 22, a second ferroelectric material layer 12, and a third metal compound layer 23. Here, the first metal compound layer 21, the first ferroelectric material layer 11, the second metal compound layer 22, the second ferroelectric material layer 12, and the third metal compound layer 23 are sequentially and successively formed by atomic layer deposition. Accordingly, since the first metal compound layer 21, the first ferroelectric material layer 11, the second metal compound layer 22, the second ferroelectric material layer 12, and the third metal compound layer 23 are produced in the same chamber and in a vacuum environment, the interface quality between the ferroelectric material layers and the metal compound layers has low defect density, thus indicating that no other oxide layer or oxide is generated in the two interfaces.

Furthermore, according to the embodiment shown in FIG. 3, the ferroelectric memory structure Z3 further includes two electrode layers 4 and 5 electrically connected to the first metal compound layer 21 and the third metal compound layer 23, respectively. However, the user can determine whether or not to provide other film layers on the two electrode layers 4 and 5 according to requirements. For example, the electrode layers 4 is connected to the first metal compound layer 21, and after other functional film layers are deposited or disposed on the third metal compound layer 23, the electrode layer 5 is then disposed on the third metal compound layer 23 to complete the ferroelectric memory element according to requirements. The present disclosure is not limited thereto.

According to certain embodiments, after the third metal compound layer 23 is deposited, plasma can be used to modify a surface of the third metal compound layer 23 to repair defects on the surface of the third metal compound layer 23.

According to certain embodiments, the first metal compound layer 21 includes a first deposition layer and a second deposition layer, and compositions of the first deposition layer and the second deposition layer are different from each other. The second metal compound layer 22 and the third metal compound layer 23 may each further include two or more deposition layers. The compositions of the deposition layers in the same metal compound layer are different. The difference in “composition” may indicate a difference in contents or a difference in proportions of the content, but the present disclosure is not limited thereto.

According to certain embodiments, the material of the first metal compound layer 21 at least includes an oxygen-containing compound or a nitrogen-containing compound formed of any one of tantalum, titanium, and aluminum. For example, the material can be tantalum nitride, titanium nitride, or aluminum nitride. In certain embodiments, the material may also be aluminum oxynitride or titanium oxynitride, and is not limited in the present disclosure.

The abovementioned material of the electrode layer 4 (or the electrode layer 5) can be a pure metal, such as titanium, tantalum, lead, tin, niobium, or tungsten; the material can also be an alloy of the aforementioned elements; the material can also be a metallic compound, such as titanium nitride, tantalum nitride, or aluminum nitride; the material can also be a semiconductor substrate doped with Group III or Group V elements, and the present disclosure is not limited thereto.

In certain embodiments, a thickness of the material of the first metal compound layer 21 is less than or equal to 20 nm. A thickness of the second metal compound layer 22 is less than or equal to 20 nm. A thickness of the third metal compound layer 23 is less than or equal to 20 nm. According to certain embodiments, thicknesses of the materials of the aforementioned metal compound layers can be from 2 nm to 10 nm.

It should be noted that, in the same ferroelectric memory structure Z3, when two metal compound layers (e.g., the first metal compound layer 21 and the second metal compound layer 22) are present, the thickness of each of the metal compound layers may be the same or different, and the content and the proportions of the content of each of the metal compound layers can be the same or different; however, the present disclosure is not limited thereto. The same principle can be applied to a single ferroelectric memory structure Z3 including three metal compound layers (e.g., the first metal compound layer 21, the second metal compound layer 22, and the third metal compound layer 23).

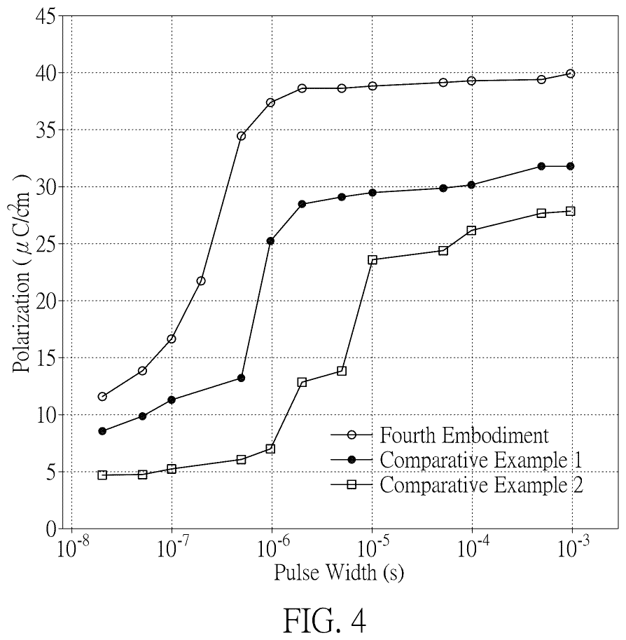

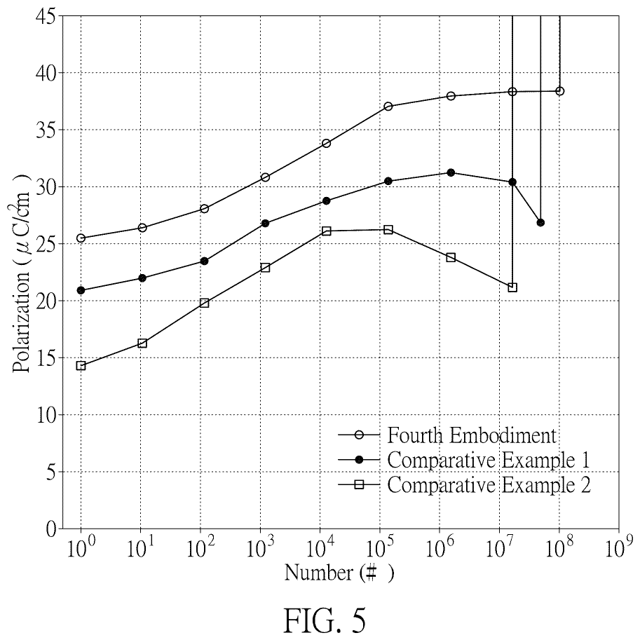

Reference is made to FIG. 4 and FIG. 5, which are respectively schematic diagrams comparing a ferroelectric memory element according to one embodiment of the present disclosure (a fourth embodiment) and a ferroelectric memory element according to the relevant art (Comparative Example 1 and Comparative Example 2). The ferroelectric memory structures used in these ferroelectric memory elements are as exemplarily shown in FIG. 1. Here, the metal compound layer used in the fourth embodiment is tantalum nitride (TaN) formed by atomic layer deposition, the metal compound layer used in Comparative Example 1 is titanium nitride (TiN) formed by atomic layer deposition, and the metal compound layer used in Comparative Example 2 is titanium nitride (TiN) formed by physical vapor deposition.

FIG. 4 shows a relationship between a pulse width and a polarization (μC/cm²). As shown in FIG. 4, under the same electric field (for example, 4MV/cm) and a pulse width of 2 μs, the polarization of the fourth embodiment of the present disclosure can substantially reach 40 μC/cm². The polarization in Comparative Example 1 is 30 μC/cm², and the polarization in Comparative Example 2 is 15 μC/cm². The performance of polarization of the fourth embodiment of the present disclosure is higher than that of Comparative Example 1 and Comparative Example 2.

FIG. 5 shows a relationship between a number of cycles and the polarization (μC/cm²). Compared with the performance of the polarization in FIG. 4 (under the conditions of an electric field of 4 MV/cm and a pulse width of 2 us), as shown in FIG. 5, the number of cycles of the fourth embodiment of the present disclosure can reach 10⁸. The number of cycles in Comparative Example 1 is 5×10⁷, and the number of cycles in Comparative Example 2 is 10⁷. Accordingly, the performance of the number of cycles of the fourth embodiment of the present disclosure is greater than that of Comparative Example 1 and Comparative Example 2.

According to the results shown in FIG. 4 and FIG. 5, the successive forming process of the metal compound layer and the two ferroelectric material layers of the present disclosure (i.e., a continuous growth in a deposition process) prevents the presence (or only allows for the presence of a tiny amount) of oxides or contaminants in the metal compound layer and the ferroelectric material layer, thereby effectively reducing the defect density of the interface between the metal compound layer and the ferroelectric material layer, and improving the performance of the ferroelectric memory element.

### Beneficial Effects of the Embodiments

The ferroelectric memory structure of the present disclosure can be used in memory elements having different structures such as FeRAM, FeFET, and FTJ memories.

In conclusion, in the ferroelectric memory structure provided by the present disclosure, by virtue of “the first ferroelectric material layer and the first metal compound layer being successively formed by an atomic layer deposition,” the first metal compound layer can be a blocking layer to block atomic diffusion and reduce interface defect density between ferroelectric material layers and electrode layers, thereby reducing an interface resistance value and adjusting a stress of the ferroelectric material layer. The ferroelectric memory structure can be applied to ferroelectric memory elements to achieve characteristics of low voltage, high-speed operation, and high reliability.

Furthermore, according to certain embodiments, the ferroelectric memory structure includes two ferroelectric material layers and one metal compound layer. The one metal compound layer serves as a division layer, such that crystallographic orientations of the two ferroelectric material layers are consistent, thereby improving ferroelectric characteristics of the ferroelectric memory element. Therefore, when the ferroelectric memory structure is used in the ferroelectric memory element, characteristics of low voltage, high-speed operation and high reliability can also be realized.

Moreover, according to certain embodiments, a material of the metal compound layer is TaN. Compared to a metal compound layer formed by physical vapor deposition, the metal compound layer formed by atomic layer deposition is used as an intermediate layer that is able to effectively improve durability and a crash time of the ferroelectric memory element that uses the metal compound layer, such that the ferroelectric memory element can sustain a continuous operation under a high electric field for a long period of time.

In addition, according to certain embodiments, the ferroelectric memory structure includes two ferroelectric material layers and one metal compound layer. Since the one metal compound layer divides the two ferroelectric material layers, after an annealing process, a crystal size of the ferroelectric material can be effectively lowered, and goals of improving an operation speed and lowering an operation voltage can be further achieved.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A ferroelectric memory structure, comprising:
a first ferroelectric material layer; and
a first metal compound layer adjacently attached to one surface of the first ferroelectric material layer, wherein the first ferroelectric material layer and the first metal compound layer are successively formed by an atomic layer deposition process.

2. The ferroelectric memory structure according to claim 1, further comprising: a second metal compound layer adjacently attached to another surface of the first ferroelectric material layer, wherein the first metal compound layer, the first ferroelectric material layer, and the second metal compound layer are sequentially and successively formed by the atomic layer deposition process.

3. The ferroelectric memory structure according to claim 2, further comprising: an electrode layer connected to the first metal compound layer or the second metal compound layer.

4. The ferroelectric memory structure according to claim 1, further comprising: a second ferroelectric material layer, wherein the first ferroelectric material layer, the first metal compound layer, and the second ferroelectric material layer are sequentially and successively formed by the atomic layer deposition process.

5. The ferroelectric memory structure according to claim 4, further comprising: an electrode layer connected to the first ferroelectric material layer or the second ferroelectric material layer.

6. The ferroelectric memory structure according to claim 1, further comprising: a second metal compound layer, a second ferroelectric material layer, and a third metal compound layer, wherein the first metal compound layer, the first ferroelectric material layer, the second metal compound layer, the second ferroelectric material layer, and the third metal compound layer are sequentially and successively formed by the atomic layer deposition process.

7. The ferroelectric memory structure according to claim 6, further comprising: an electrode layer connected to the first metal compound layer or the third metal compound layer.

8. The ferroelectric memory structure according to claim 1, wherein the first metal compound layer includes a first deposition layer and a second deposition layer, and compositions of the first deposition layer and the second deposition layer are different from each other.

9. The ferroelectric memory structure according to claim 1, wherein the material of the first metal compound layer includes at least an oxygen-containing compound or a nitrogen-containing compound formed of any one of tantalum, titanium, and aluminum.

10. The ferroelectric memory structure according to claim 1, wherein a thickness of the first metal compound layer is less than or equal to 20 nm.
